(19) United States
(12) Patent Application Publication
(10) Pub. No.: US 2011/0011638 A1
(43) Pub. Date: Jan. 20, 2011

(54) SHIELDING TAPE WITH EDGE INDICATOR

(76) Inventors: Paul Gemme, PINEHURST, NC (US); Leonard Visser, Gilbert, AZ (US)

Correspondence Address: SQUIRE SANDERS & DEMPSEY LLP, 1 East Washington Street, SUITE 2700, PHOENIX, AZ, 85004, US

(21) Appl. No.: 12/605,868

(22) Filed: Oct. 26, 2009

Related U.S. Application Data
(60) Provisional application No. 61/226,249, filed on Jul. 16, 2009.

(51) Int. Cl. H05K 9/00; H01B 9/02

(52) U.S. Cl. 174/350; 174/102 R

(57) ABSTRACT

The present invention comprises a shielding tape comprising at least one shielding layer, at least one separator layer, a first (inner) edge, and a second (outer) edge. The shielding tape further includes an indicator extending along at least a portion of the outer edge. The indicator is for identifying the outer edge when the outer edge overlaps the inner edge when the shielding tape is positioned onto a cable. Alternatively, both edges may have an indicator. The present invention makes it easy to locate the outer edge of the shielding tape for an installer wishing to remove at least some of the shielding tape before crimping or compressing a connector onto the end of a cable.

### CROSS REFERENCE TO RELATED APPLICATIONS

This nonprovisional utility application claims priority to U.S. Provisional Patent Application No. 61/226,249, filed Jul. 16, 2009 titled “Shielding Tape With Edge Indicator,” the disclosure of which is fully incorporated herein by reference for all purposes.

### BACKGROUND

Shielding is used a variety of cables to reduce electrical interference that could affect a signal travelling through the cable. The shielding also helps prevent the signal from radiating from the cable and interfering with other devices. One such type of shielding includes a layer of aluminum or other shielding material (such as silver or copper) laminated on a separating layer, such as a plastic, e.g., polyethylene terephthalate (“PET”) or polypropylene (“PP”). This type of shielding, which combines layers of shielding material and separating layers, is often referred to as either “foil,” “laminated tape,” “shielding tape,” “shielding laminate tape,” and combinations or variations thereof. In some cables, such as coaxial cables, multiple layers of shielding tape are sometimes employed.

When used, shielding tape is wrapped about the longitudinal axis of a cable, overlapping itself to some degree to ensure a proper level of shielding. In some shielded cables, it is desirable to be able to detect the outer edge of the overlapping shielding tape. In coaxial cables, for example, a portion of the outer layer of shielding tape must be removed to allow an installer to expose, and peel back, a layer of aluminum braiding before compressing or crimping a connector (such as an F-type connector) onto the end of the cable. Conventional shielding tape, however, is of uniform color, making the outer edge of the overlap difficult and time-consuming to locate.

### SUMMARY OF THE INVENTION

The present invention comprises a shielding tape comprising at least one shielding layer, at least one separator layer, a first (inner) edge, and a second (outer) edge. The shielding tape further includes an indicator extending along at least a portion of the outer edge. The indicator is for identifying the outer edge when the outer edge overlaps the inner edge when the shielding tape is positioned onto a cable. Alternatively, both edges may have an indicator.

The present invention also includes a cable having a center conductor and an outer shielding tape as described above that surrounds the center conductor. The shielding tape may surround the conductor directly (i.e., there are no intervening structures between the conductor and the tape) or indirectly (i.e., there are one or more intervening structures between the conductor and the tape, such as a dielectric, braiding, or other shielding tape). The present invention makes it easy to locate the outer edge of the shielding tape for an installer wishing to remove at least some of the shielding tape before crimping or compressing a connector onto the end of a cable.

### BRIEF DESCRIPTION OF THE DRAWINGS

FIG. 1 shows one preferred embodiment of a cable including a shielding tape according to the invention.

### DESCRIPTION OF PREFERRED EMBODIMENTS OF THE INVENTION

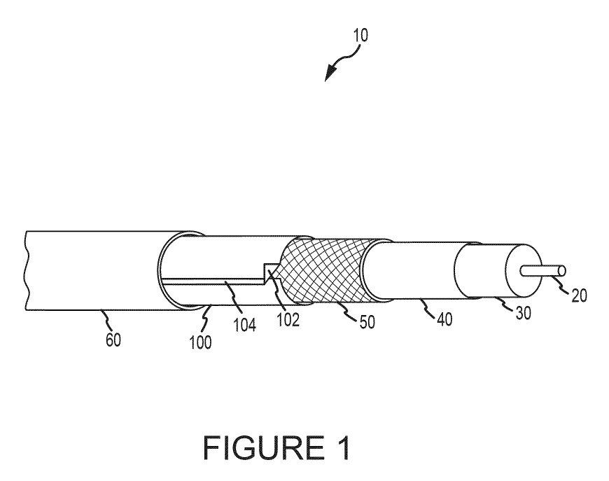

Turning now to the Figures, where the purpose is to describe a preferred embodiment of the invention and not to limit same, FIG. 1 shows a coaxial cable 10 that includes a shielding tape 100 according to the invention. Cable 10 includes a center conductor 20, a dielectric 30, an inner foil 40, a braid material 50, an outer foil 100, and an outer jacket 60.

The shielding tape 100 (also referred to herein as “outer foil”) is wrapped about the longitudinal axis of the cable 10 with the inner edge (not shown) of shielding tape 100 in direct contact with the braid 50, and the outer edge 102 (denoted by the label “overlap” in FIG. 1) overlapping the inner edge. The outer edge 102 includes an indicator 104 that identifies edge 102 of the shielding tape 100 (the indicator is also referred to in FIG. 1 as the “stripe”). Both edges of the shielding tape 100 may include an indicator 104 so that shielding tape 100 is not handed when used.

The indicator may be visual, tactile, or both. The indicator may be continuous, as shown, or intermittent. A shielding tape in accordance with the present invention may include any number of separate indicators.

The preferred indicator 104 according to the present invention is visual and may be any size, shape, color, or design. In the preferred embodiment, the indicator 104 is a continuous solid colored line about 1-2 mm wide. The visual indicator 104 is of a different color than the rest of the shielding tape to help identify the location of the outer edge 102. The visual indicator 104 may also be intermittently placed along the outer edge 102 and formed in any suitable manner. The indicator 104 in FIG. 1, for example, can be applied to the edge 102 of the shielding tape 100 using a printing process, such as offset printing with a wheel or transfer from a felt pad containing liquid ink. The visual indicator 104 may instead be applied in any other suitable manner, such as by laser etching or embossing.

A tactile indicator according to the present invention may include any number and combination of tactile indicators to help identify the outer edge of the laminated foil tape, such as raised portions or indentations in the tape and/or a sawtooth or other pattern cut along the outer edge of the tape. The tactile indicator may also serve as a visual indicator (e.g., in the case of a pattern cut in the edge of the outer edge).

A preferred cable with which shielding tape 100 is used is a coaxial cable 10 as shown in FIG. 1. Coaxial cable 10 comprises a center conductor 20 preferably formed from copper-clad steel and is about 0.0403″ in diameter. Surrounding the center conductor 20 is a dielectric 30 that is about 0.18″ in diameter and preferably formed from foam polyethylene. An inner foil 40 formed from about 0.003″ thick shielding tape is wrapped around, and preferably bonded to, the dielectric 30. Surrounding the inner foil 40 is a braid 50 formed from 34-gauge aluminum wire. The shielding tape 100 is wrapped around the braid 50, wherein the edge of the outer foil 100 that overlaps itself is identified by visual indicator 104 along the edge of the shielding tape 100. The edge of the outer foil 100 may overlap itself by between about 18% to about 35%, with an overlap of about 21% being most common. A jacket preferably formed from polyvinyl chloride (“PVC”) that is about 0.273″ in diameter and about 0.03″ thick surrounds the outer foil.

The shielding tape of the present invention may be used in conjunction with any other type of shielded cable, such as shielded twisted-pair cabling. The shielding tape of the present invention may also be used to surround any type of conductor, insulator, or other component of a shielded cable. For example, the shielding tape may surround a conductor directly (i.e., there are no intervening structures between the conductor and the tape) or indirectly (i.e., there are one or more intervening structures between the conductor and the tape, such as a dielectric, braiding, or other shielding).

Having thus described preferred embodiments of the invention, other variations and embodiments that do not depart from the spirit of the invention will become apparent to those skilled in the art. The scope of the present invention is thus not limited to any particular embodiment, but is instead set forth in the appended claims and the legal equivalents thereof. Unless expressly stated in the written description or claims, the steps of any method recited in the claims may be performed in any order capable of yielding the desired result.

What is claimed is:

1. A cable comprising:
(a) a center conductor;
(b) an outer shielding tape surrounding the center conductor, the outer shielding tape comprising:
(i) an inner edge;
(ii) an outer edge that overlaps the inner edge; and
(iii) an indicator extending along at least a portion of the outer edge, the indicator for identifying the outer edge.

2. The cable of claim 1, wherein the indicator comprises a visual indicator.

3. The cable of claim 2, wherein the visual indicator is a solid line.

4. The cable of claim 2, wherein the shielding tape comprises a first color and the visual indicator comprises a second color, and wherein the first color and second color are different.

5. The cable of claim 2, wherein the outer edge comprises a visual indicator at intervals along the outer edge.

6. The cable of claim 2, wherein the outer edge comprises a continuous visual indicator along the outer edge.

7. The cable of claim 1, wherein the indicator comprises a tactile indicator.

8. The cable of claim 7, wherein the tactile indicator is also a visual indicator.

9. The cable of claim 7, wherein the tactile indicator comprises one or more raised areas along the outer edge.

10. The cable of claim 7, wherein the tactile indicator comprises one or more indentations along the outer edge.

11. The cable of claim 7, wherein the tactile indicator comprises a pattern cut into the outer edge.

12. The cable of claim 11, wherein the pattern is a sawtooth pattern.

13. The cable of claim 1, wherein the indicator comprises a visual indicator and a tactile indicator.

14. A shielding tape comprising:
(a) a shielding layer bonded to a separator layer;
(b) an inner edge;
(c) an outer edge; and
(d) an indicator extending along at least a portion of the outer edge, the indicator for identifying the outer edge when the outer edge overlaps the inner edge when the shielding tape surrounds a conductor in a cable.

15. The shielding tape of claim 14, wherein the indicator comprises a visual indicator.

16. The shielding tape of claim 15, wherein the visual indicator includes a solid line.

17. The shielding tape of claim 15, wherein the shielding tape comprises a first color and the visual indicator comprises a second color, and wherein the first color and second color are different.

18. The shielding tape of claim 15, wherein the outer edge comprises a visual indicator at intervals along the outer edge.

19. The shielding tape of claim 15, wherein the outer edge comprises a continuous visual indicator along the outer edge.

20. The shielding tape of claim 14, wherein the indicator comprises a tactile indicator.

21. The shielding tape of claim 20, wherein the tactile indicator is also a visual indicator.

22. The shielding tape of claim 20, wherein the tactile indicator comprises one or more raised areas along the outer edge.

23. The shielding tape of claim 20, wherein the tactile indicator comprises one or more indentations along the outer edge.

24. The shielding tape of claim 20, wherein the tactile indicator comprises a pattern cut into the outer edge.

25. The shielding tape of claim 24, wherein the pattern is a sawtooth pattern.

26. The shielding tape of claim 14, wherein the indicator comprises a visual indicator and a tactile indicator.

27. The shielding tape of claim 14, wherein both edges include an indicator.

28. The cable of claim 1, wherein both edges include an indicator.
